(19) United States
(12) Patent Application Publication
(10) Pub. No.: US 2024/0186285 A1
(43) Pub. Date: Jun. 6, 2024

(54) PRE-STACKING MECHANICAL STRENGTH ENHANCEMENT OF POWER DEVICE STRUCTURES

(71) Applicant: SEMICONDUCTOR COMPONENTS INDUSTRIES, LLC, Scottsdale, AZ (US)

(72) Inventors: Yusheng LIN, Phoenix, AZ (US); Francis J. CARNEY, Mesa, AZ (US); Chee Hiong CHEW, Seremban (MY); Shunsuke YASUDA, Ora-Gun (JP)

(73) Assignee: SEMICONDUCTOR COMPONENTS INDUSTRIES, LLC, Scottsdale, AZ (US)

(21) Appl. No.: 18/444,221

(22) Filed: Feb. 16, 2024

Related U.S. Application Data
(62) Division of application No. 16/661,633, filed on Oct. 23, 2019.
(60) Provisional application No. 62/871,935, filed on Jul. 9, 2019.

(51) Int. Cl. H01L 23/00; H01L 21/02; H01L 21/56; H01L 21/60

(52) U.S. Cl. CPC H01L 24/94; H01L 21/02013; H01L 21/02016; H01L 21/561; H01L 2021/60015; H01L 2224/94

(57) ABSTRACT

A method includes placing a coupling mechanism material layer on a backside of a wafer having power devices fabricated on a frontside thereof, and placing conductive spacer blocks on the coupling mechanism material layer on a backside of the selected wafer. The method further includes activating the coupling mechanism material to bond the conductive spacer blocks to the backside of the selected wafer, and singulating the wafer to separate the vertical device stacks, each of the singulated vertical device stacks including a device die bonded to, or fused with, a conductive spacer block.

### CROSS-REFERENCE TO RELATED APPLICATIONS

This application claims the benefit of U.S. Provisional Patent Application No. 62/871,935, filed on Jul. 9, 2019, the entire contents of which is incorporated herein by reference.

### TECHNICAL FIELD

This description relates to wafer-level packaging of power devices.

### BACKGROUND

Modern high-power devices can be fabricated using advanced silicon technology to meet high power requirements. These high-power devices (e.g., silicon power devices such as an insulated-gate bipolar transistor (IGBT), a fast recovery diode (FRD), etc.) may be packaged in single-side cooling (SSC) or dual-side cooling (DSC) power modules. High-power devices that can deliver or switch high levels of power can be used in, for example, vehicles powered by electricity (e.g., Electric vehicles (EVs), hybrid electric vehicles (HEVs) and plug-in-electric vehicles (PHEV)). The larger size and thicknesses of the high-power device die can create problems such as die warpage and die damage during packaging of the high-power devices for use in circuit packages or power modules (e.g., SSC or DSC power modules), or during stress tests of the fabricated high-power devices.

### SUMMARY

In a general aspect, a method includes coupling a conductive spacer block to a carrier, coupling a solder or sinter material layer to the conductive spacer block, and coupling a device die to the solder or sinter material layer. The method further includes reflowing the solder material layer or sintering the sintering material to bond the device die and the conductive spacer block to form a vertical device stack, and removing the vertical device stack from the carrier as a single pre-formed unit.

In a general aspect, a method includes placing a coupling mechanism material layer on a backside of a wafer having power devices fabricated on a frontside thereof, placing conductive spacer blocks on the coupling mechanism material layer on a backside of the selected wafer, and activating the coupling mechanism material to bond the conductive spacer blocks to the backside of the selected wafer. The method further includes singulating the wafer to separate the vertical device stacks, each of the singulated vertical device stacks including a device die bonded to, or fused with, a conductive spacer block.

In a general aspect, a method includes placing a coupling mechanism material layer on a backside of a wafer having power devices fabricated on a frontside thereof, and placing a one-piece grid of conductive spacer blocks on the coupling mechanism material layer on the backside of the selected wafer, and activating the coupling mechanism material layer to bond the conductive spacer blocks in the one-piece grid of conductive spacer blocks to the backside of the selected wafer. The method further includes singulating the wafer to separate vertical device stacks, each of the singulated vertical device stacks including a device die bonded to, or fused with, a conductive spacer block.

In a general aspect, a pre-formed vertical device stack includes a vertical arrangement of thin device die having a device fabricated on a front side thereof and a conductive spacer block bonded to a backside of the thin device die via a coupling mechanism. The conductive spacer block is bonded to the thin device die reinforcing a mechanical strength of the thin device die allowing the vertical device stack to be moved and placed in a circuit package as a single pre-formed unit.

In example implementations, the thin device die can be about 100 microns thick or less, and can include a power device having a size that is greater than 25 square millimeters. The conductive spacer block can have a thickness greater than about 200 microns.

The details of one or more implementations are set forth in the accompanying drawings and the description below. Other features will be apparent from the description and drawings, and from the claims.

### BRIEF DESCRIPTION OF THE DRAWINGS

FIG. 1 is a block diagram illustrating an example pre-formed vertical device stack.

FIG. 2 illustrates an example vertical device stack disposed as a single pre-formed unit in a circuit package.

FIG. 3 illustrates an example method that involves some handling of individual device die when making pre-formed vertical device stacks.

FIGS. 4A-4E schematically illustrate a cross-sectional view of a carrier as it is being processed to make pre-formed vertical device stacks by the method of FIG. 3.

FIG. 5 illustrates an example method that avoids handling of individual device die by using wafer-level processing steps when making pre-formed vertical device stacks for assembly of a circuit package.

FIGS. 6A-6G schematically illustrate views of a wafer as it is being processed to make pre-formed vertical device stacks by the method of FIG. 5.

FIG. 7 illustrates another example method that avoids handling of individual device die by using wafer-level processing steps when making pre-formed vertical device stacks for assembly of a circuit package.

FIGS. 8A-8C illustrate views of a wafer as it is being further processed by the method of FIG. 7.

FIG. 9 is a schematic illustration of different semiconductor device die having different thicknesses in a circuit package.

FIG. 10 is a schematic illustration of a pre-formed vertical device stack having a passivating layer deposited on its sides.

FIG. 11 illustrates an example method for depositing a passivating layer on the sides of pre-formed vertical device stacks using wafer-level processing steps.

FIG. 12 illustrate a view of a wafer as it is being further processed by the method of FIG. 11.

### DETAILED DESCRIPTION

Modern high-power semiconductor devices can be fabricated using advanced silicon technologies to meet the high power requirements. The power devices (such as an insulated-gate bipolar transistor (IGBT), a fast recovery diode (FRD), etc.) may be fabricated using, for example, one or more of silicon (Si), silicon carbide (SIC), and gallium nitride (GaN) materials, or other semiconductor materials. The power devices may be fabricated on thinned semiconductor wafers (e.g., silicon wafers) that are, for example, only about 100 microns thick or less. This results in high-power device die sizes that are larger and thinner than power device die sizes for traditional power devices fabricated on regular substrates (i.e., on un-thinned silicon wafers) using conventional silicon technologies. However, large-size, thin semiconductor device die obtained from the thinned semiconductor wafers are subject to damage from mechanical and/or thermal stresses, including warping, chipping, or breaking in further processing and assembly steps (e.g., for assembly of circuit packages).

The present disclosure describes techniques that avoid individual processing and/or handling of large-size and thin device die in the assembly of circuit packages to avoid the mechanical or structural drawbacks (e.g., die warpage, chipping, etc.) of the large-size and thin device die. Individual thin device die are mechanically and structurally reinforced by bonding a supporting spacer block to the die, in accordance with the principles of the present disclosure. The thickness of the thin device die is augmented by the thickness of the supporting spacer block in the die-supporting block combination. The die-supporting block combination (which is arranged as a vertical device stack) is processed and handled as a single pre-formed unit in the assembly of circuit packages. The processing techniques described herein can prevent or reduce damage from mechanical and/or thermal stresses, including warping, chipping, or breaking in processing and assembly steps (e.g., for assembly of circuit packages). The processing techniques described herein can result in relatively large power devices that could not previously be achieved using known manufacturing techniques. The processing techniques described herein can result in, for example, desirable joint quality between die and thermally and/or electrically conductive materials.

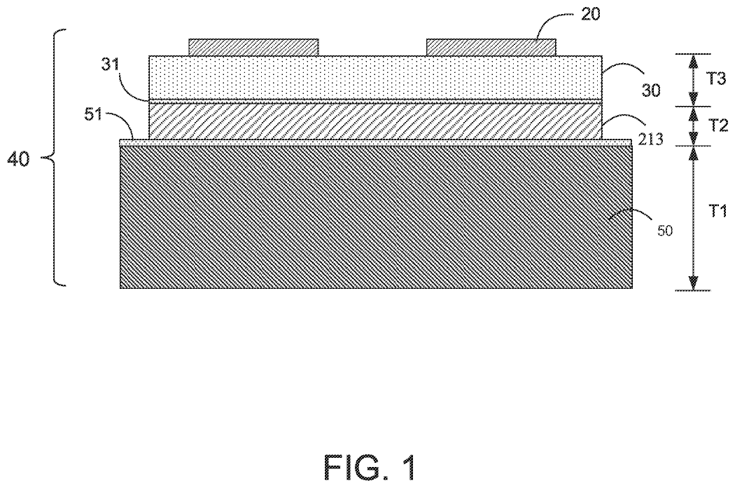

FIG. 1 is a cross-sectional sectional view of an example pre-formed vertical device stack 40 that may be processed and handled as a single pre-formed unit in the assembly of circuit packages, in accordance with the principles of the present disclosure.

Vertical device stack 40 may include a thin device die 30 on which one or more power devices (e.g., device 20) are fabricated, a supporting spacer block (e.g., conductive spacer block 50), and a coupling mechanism 213. Thin device die 30 may have a thickness T3 that is in a range of about 10 microns to 200 microns. In an example implementation, thin device die 30 may have a thickness of about 80 microns. Conductive spacer block 50 may have a thickness T1 in a range of about 200 microns to 2000 microns (which is 2 to 10 times greater than T3), and coupling mechanism 213 may have a thickness T2 in a range of about 50 microns to 200 microns (which is approximately the same range as T1). In example implementations, conductive spacer block 50 may have a thickness T1 of about 500 microns or greater, and coupling mechanism 213 may have a thickness T2 of about 100 microns. In pre-formed vertical device stack 40, conductive spacer block 50 is bonded or fused to thin device die 30, for example, via coupling mechanism 213 (e.g., a solder), to mechanically and structurally reinforce thin device die 30. Conductive spacer block 50 may be coated with a metal layer 51 (e.g., a plated silver layer which is greater than 2 microns thick) and thin device die 30 may be coated or plated with a back metal layer 31 (e.g., a titanium/nickel/silver layer about 2 microns thick) which promote bonding or fusion of conductive spacer block 50 and thin device die 30 via coupling mechanism 213.

The combination of the conductive spacer block 50 bonded to thin device die 30 reinforces the mechanical strength of device die and effectively increases the thickness of the thin device die (e.g., from a device die thickness of T3 to a total vertical stack thickness of (T1+T2+T3) as shown in FIG. 1).

Methods for making the pre-formed device die-block combinations (e.g., pre-formed vertical stack 40) are described herein.

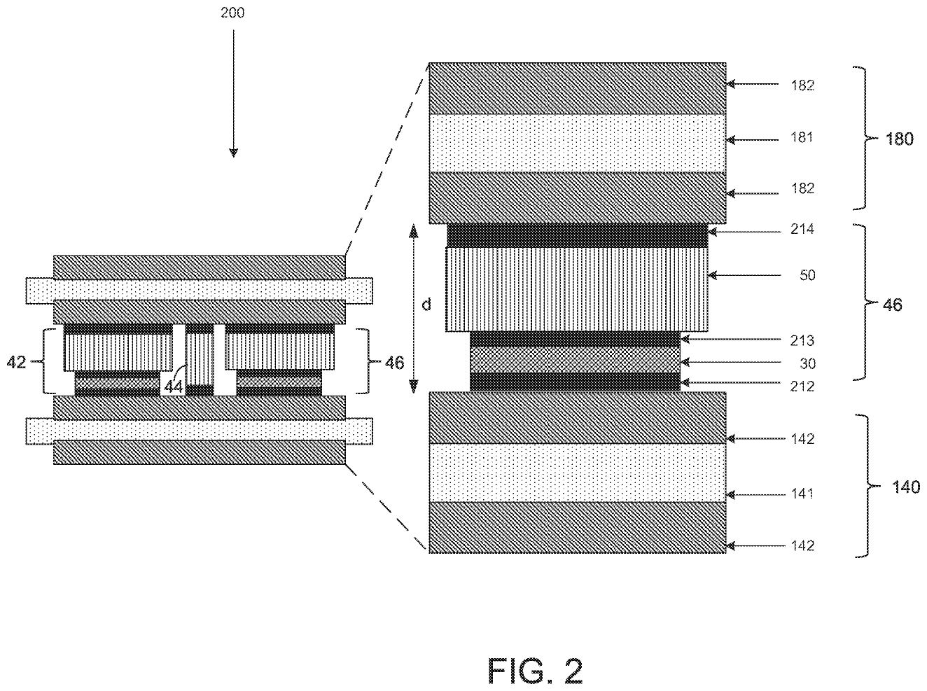

The pre-formed device die-block combination (i.e., pre-formed vertical stack 40) can be handled as a single pre-formed unit in further processes for assembling circuit packages as described herein (whereas in the traditional methods, the thin device die by itself and conductive spacer block by itself are handled as independent single units in later assembly processes). FIG. 2 shows an example of the use of pre-formed vertical device stacks in an example circuit package 200 (also can be referred to as a dual-side-cooled power module).

Example circuit package 200 may include pre-formed vertical device stack 46 and pre-formed vertical device stack 42, each disposed as a single pre-formed unit in the circuit package. Pre-formed vertical device stack 46 and pre-formed vertical device stack 42 may (like pre-formed vertical stack 40 shown in FIG. 1) include respective device dies that are bonded or fused to respective conductive spacer blocks that effectively increase the thicknesses of the device die. In example implementations of circuit package 200, vertical device stack 46 may (as shown, for example, in an exploded view in the right of FIG. 2)include a vertical arrangement of a power device die 30 (e.g., an insulated-gate bipolar transistor (IGBT), a fast recovery diode (FRD), etc.) that is thermally coupled on one side to a first cooling substrate (e.g., substrate 140) and thermally coupled on the other side to a conductive spacer block made of electrically and thermally conductive material (e.g., copper-molybdenum). The conductive block (e.g., a copper-molybdenum spacer) may be thermally coupled to a second cooling substrate (e.g., substrate 180).

FIG. 2 shows, for example, pre-formed vertical device stack 46 disposed between an opposing pair of substrates (i.e., substrate 140 and substrate 180) according to some implementations. Substrate 140 and substrate 180 may, for example, include dielectric layers 141 and 181 (e.g., a ceramic layer, a polymer layer, etc.) that are plated, coated, or printed, on both sides, with copper or other electrically conductive material layers (e.g., conductive layer 142, conductive layer 182). Dielectric layers 141 and 181 may be made from electrically insulating, but thermally conductive materials (e.g., Zr-doped alumina). In some implementations, conductive layer 142 and conductive layer 182 may be, or can include, a copper layer.

Pre-formed vertical device stack 46 may, for example, include a device die 30 (e.g., a power IGBT, or FRD) that is coupled (e.g., bonded) on one side to substrate 140 and on another side to a conductive spacer block 50. Conductive spacer block 50 is coupled on one side to substrate 180 and on another side to device die 30. The couplings in the vertical device stack structure (i.e., coupling mechanism 212 between substrate 140 and device die 210, coupling mechanism 213 between device die 210 and conductive spacer 50, and coupling mechanism 214 between conductive spacer 50 and substrate 180) can include, or can be, for example, a solder, a sinter, a fusion bond, and/or so forth.

In example implementations, a circuit package (e.g., a dual-side-cooled power module package) may include more than one semiconductor device die enclosed within a pair of opposing substrates (e.g., substrate 140 and substrate 180). Each semiconductor die may be arranged in a respective pre-formed vertical device stack (e.g., vertical device stack 46, vertical device stack 42, etc.) that includes a conductive spacer block (e.g., a copper block). In the example shown in FIG. 2, more than one pre-formed vertical device stacks (i.e., vertical device stack 46 and vertical device stack 42) are enclosed within the pair of opposing substrates (e.g., substrates 140, 180) that are separated by an inter-substrate distance d. A conductive pillar (e.g., copper pillar) may be disposed between the pair of opposing substrates to provide conductive paths (not shown) between vertical device stack 46 and vertical device stack 42.

In contrast to the use of pre-formed vertical device stacks, traditional methods of assembling a circuit package (e.g., a dual-side-cooled power module package, circuit package 200) including a vertical device stack (e.g., similar to vertical device stack 46) may involve individually picking, aligning, and placing (e.g., coupling) individual stack components (e.g., device die 30, conductive spacer block 50, etc.) on substrate 140 or substrate 180. Several joining steps may be used for bonding or fusing the different components together (e.g., by forming inter-component coupling mechanisms 212, 213, and 214, etc.). As noted previously, when device die 30 is large in size and thin, it is susceptible warping, chipping, or breaking in the traditional methods of assembling vertical device stack 46 and circuit package 200.

In accordance with the principles of the present disclosure, methods that facilitate use of large-size and thin device die in processing and assembly operations (e.g., to make pre-formed vertical device stacks 40, 42, and 46, etc., and circuit package 200) are described herein. The described methods avoid the mechanical or structural drawbacks (e.g., die warpage, chipping, etc.) of using the large-size and thin device die in vertical device stacks and circuit packages.

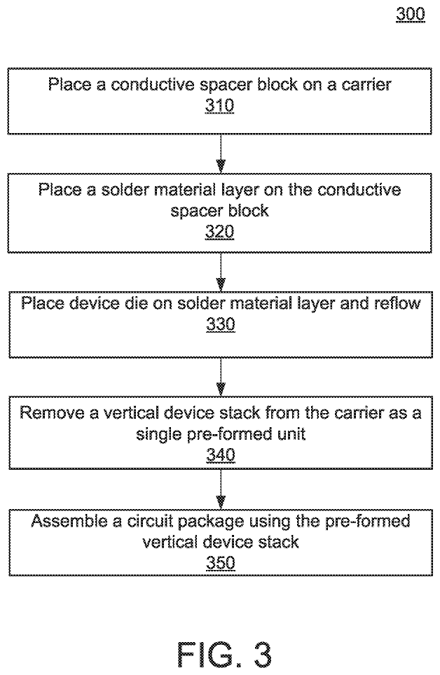

FIG. 3 shows an example method 300 that involves some handling of individual device die (e.g., device die 30) when making pre-formed vertical device stacks (e.g., pre-formed vertical device stack 40) but minimizes (or reduces) handling of the individual device die itself in assembly of a dual-side-cooled power module (e.g., circuit package 200, FIG. 2), in accordance with the principles of the present disclosure. The pre-formed vertical device stacks are device die-block combinations in which a spacer block structurally reinforces individual device die.

Method 300 includes placing a conductive spacer block on a carrier (310). Placing a conductive spacer block on a carrier 310 may include using a pick-and place-tool to place (also can be referred to as coupling) conductive blocks made of metal or conductive metal alloys, for example, in an array on temporary carrier. Further, placing a conductive spacer block on the carrier 310 may include preparing a top surface of the spacer blocks with a metal layer coating to promote bonding or fusion with other components at a later step in method 300.

In some implementations, the method can include placing a solder material layer on the conductive space block (320). The method can include placing a device die on solder material layer and reflowing the solder (330). Placing a device die on solder material layer and reflowing the solder 330 may include coating or plating the device die with a back metal layer to promote bonding or fusion with the spacer blocks via the coupling mechanism.

The method 300 can include removing the pre-formed vertical device stack from the carrier as a single unit (340), and assembling a circuit package (e.g., circuit package 200, FIG. 2) using the pre-formed vertical device stack (350). The pre-formed vertical device stack includes the conductive spacer block bonded to, or fused with, the device die.

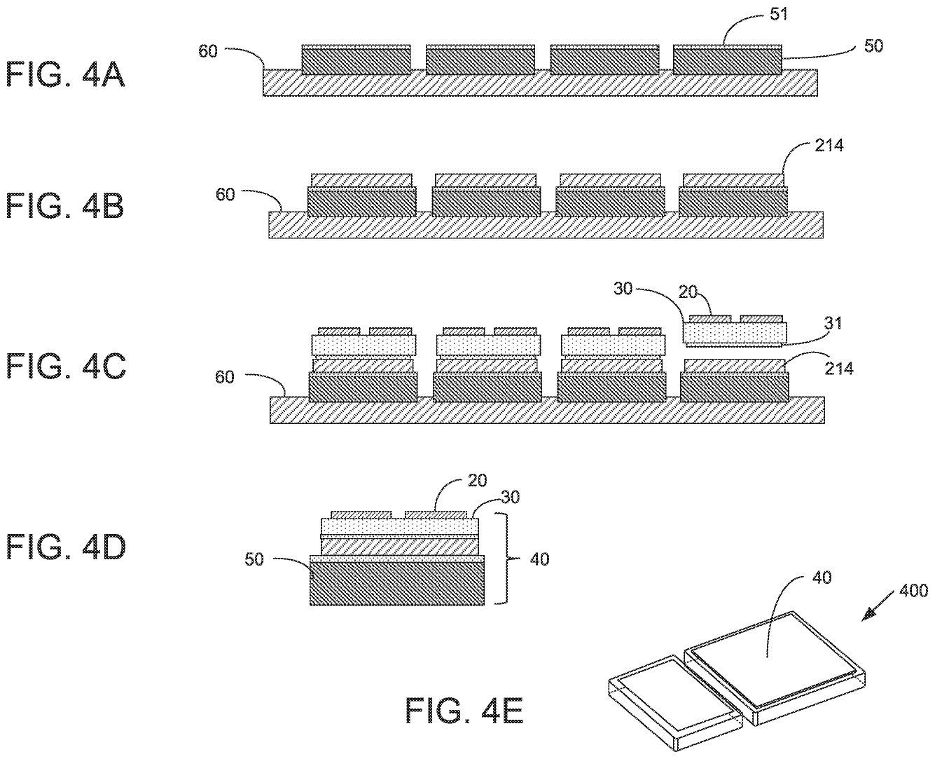

FIGS. 4A-4E schematically illustrate a cross-sectional view of a carrier as it is being processed to make pre-formed vertical device stacks by method 300 shown in FIG. 3.

FIG. 4A shows conductive spacer blocks (e.g., conductive spacer block 50) being placed on a temporary carrier 60 (as described at step 310 of method 300 (FIG. 3)). The conductive spacer block may, for example, be made of metal or conductive metal alloys (e.g., copper (Cu), aluminum (Al), copper-molybdenum (CuMo), aluminum silicon carbide composite (AlSiC), aluminum silicon magnesium alloy (AlSiMg), etc.). A pick-and place-tool may be used to place the spacer blocks, for example, in an array on temporary carrier 60. A top surface of the spacer blocks may be prepared with a metal layer (e.g., silver layer) coating to promote bonding or fusion with other components (e.g., at a later step 330 in method 300 (FIG. 3)).

FIG. 4B shows a coupling mechanism 214 (e.g., a solder) placed on spacer blocks (e.g., conductive spacer block 50) that are supported by temporary carrier 60 (as described at step 320 of method 300 (FIG. 3)).

FIG. 4C shows individual device die 30 are placed on the coupling mechanism 214 (e.g., a solder) placed on conductive spacer blocks 50 that are supported by temporary carrier 60 (as described at step 330 of method 300 (FIG. 3)). Individual device die 30 may be coated or plated with a back metal layer 31 (e.g., a titanium/nickel/silver layer) to promote bonding or fusion with the spacer blocks (e.g., conductive spacer block 50) via coupling mechanism 214.

Individual device die 30 (including device 20) may be obtained by dicing a substrate (e.g., silicon wafer) on which device 20 are fabricated (not shown). A pick-and place-tool may be used to align and place individual device die 30 (including device 20), for example, on coupling mechanism 214 (e.g., a solder) placed on the spacer blocks (e.g., conductive spacer block 50) (e.g., as described at step 330 of method 300 (FIG. 3)). Coupling mechanism 214 materials (e.g., solder) may be, for example, about 50 microns to 150 microns thick (e.g., 100 microns thick). Further, as described at step 330 of method 300 and as shown in FIG. 3, a reflow process (e.g., a solder reflow process) may activate coupling mechanism 214 to bond or fuse individual device die 30 to the spacer blocks (e.g., conductive spacer block 50), and thus form vertical device stack 40. Pre-formed vertical device stack 40 is a device-block combination in which the bonded or fused conductive spacer blocks 50 structurally reinforce individual device die 30 (which may be large-sized and thin).

FIG. 4D shows an individual pre-formed vertical device stack 40 that may have been picked and removed from temporary carrier 60 (e.g., at step 340 of method 300 (FIG. 3)). The bonded or fused spacer blocks (e.g., conductive spacer block 50) in individual vertical device stacks 40 structurally reinforce individual device die 30.

FIG. 4E schematically shows use of an individual pre-formed vertical device stack 40 in assembly of circuit packages (e.g., circuit package 400) (e.g., at step 350 of method 300 (FIG. 3)). In circuit package 400, the individual vertical device stack 40 (in which the bonded or fused spacer blocks structurally reinforce individual device die 30) may be positioned between, and in thermal contact with, a pair of opposing substrates (e.g., substrate 140 and substrate 150) (e.g., as shown and described for circuit package 200 (FIG. 2)).

In accordance with the principles of the present disclosure, a conductive spacer block can be bonded to each device die fabricated on a substrate (e.g., silicon wafer), for example, in a wafer level step, before the device die are diced or separated from the substrate. In example implementations, the device die may be about 100 microns thick or less. The conductive spacer block may be several times thicker (e.g. about 200 microns to 2500 microns thick or greater). The conductive spacer block may, for example, be made of a metal or a conductive metal alloy (e.g., copper (Cu), aluminum (Al), copper-molybdenum (CuMo), aluminum silicon carbide composite (AlSiC), aluminum silicon magnesium alloy (AlSiMg), etc.). The device die-block combination is then diced and separated from the substrate. This pre-formed device die-block combination is used as a single unit (e.g., as a pre-formed vertical stack) in further processes for assembling circuit packages (e.g., circuit package 200) (whereas in the traditional methods, the dice device die by itself and conductive spacer block by itself are handled as independent single units in the further processes). The combination of the conductive spacer block bonded to the device die reinforces the mechanical strength of device die and effectively increases the thickness of the thin device die (e.g., as shown and described for device die 30 in pre-formed vertical stack 40 (FIG. 1)). Further, since the device die-block combinations are formed in a wafer level step before dicing, the individual device die (which may be thin and large in size) are not handled individually in an unreinforced state, thus avoiding the risk of warping, chipping, or breaking.

The device dies (e.g., device die 30) used for making the pre-formed device die-block combinations in one or more wafer level steps may include devices (e.g., devices 20) fabricated on a semiconductor substrate (e.g., a silicon wafer).

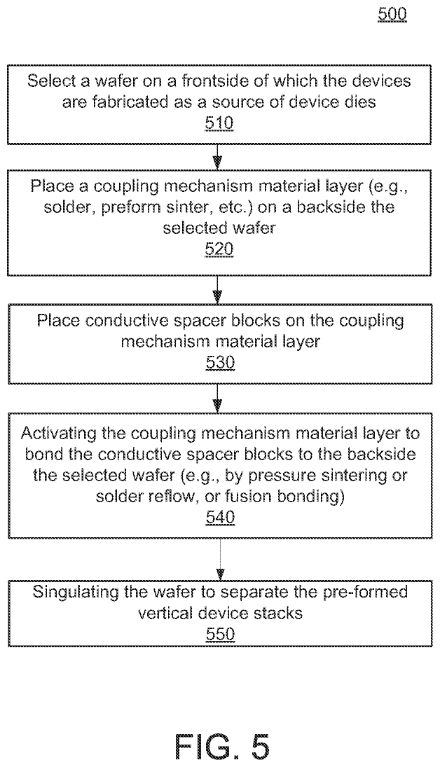

FIG. 5 shows an example method 500 that further avoids handling of individual device die (e.g., device die 30) by using wafer-level processing steps when making vertical device stacks (e.g., pre-formed vertical device stack 40) for assembly of a circuit package (e.g., circuit package 200, circuit package 400). Method 500, like method 300 (FIG. 3), results in a vertical device stack (e.g., pre-formed vertical device stack 40) that is a device die-block combination in which a conductive spacer block structurally or mechanically reinforces the individual device die (which may be large-sized and thin).

Method 500 avoids handling individually diced device die 30 by using wafer-level processing steps to make the pre-formed vertical device stacks (e.g., vertical device stack 40).

Method 500 includes selecting a wafer on a frontside of which the devices are fabricated as a source of device dies (510); placing coupling mechanism material layer (e.g., solder, preform sinter, etc.) on a backside of the selected wafer (520); placing conductive spacer blocks on the coupling mechanism material layer (530); activating the coupling mechanism material layer to bond the conductive spacer blocks to the backside of the selected wafer (540); and, singulating the wafer to separate individual vertical device stacks (550). Each of the singulated vertical device stacks includes a device die bonded or fused to a conductive spacer block.

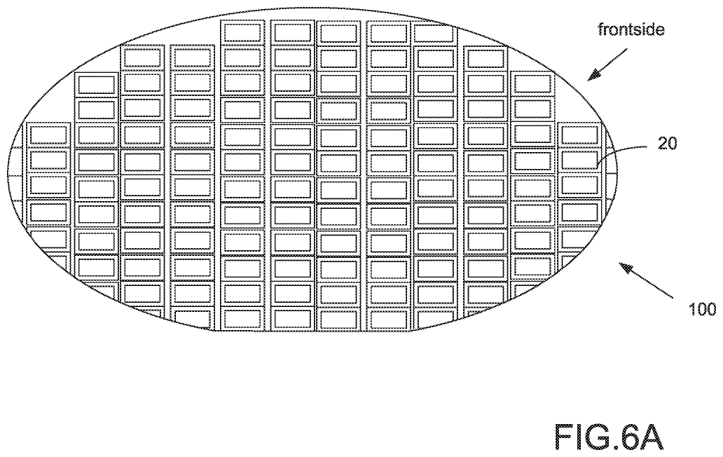

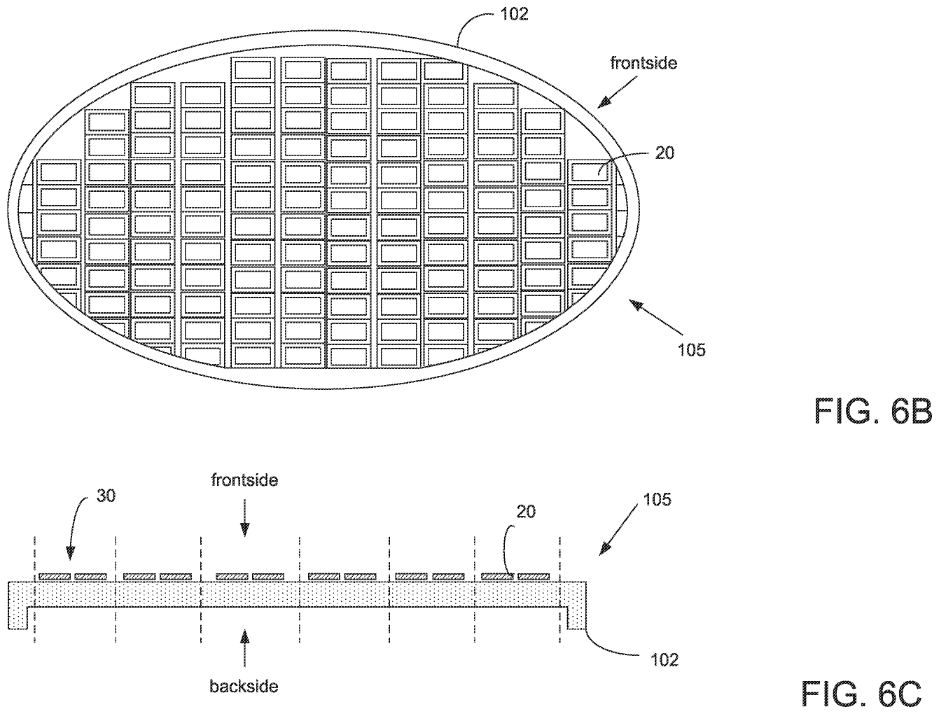

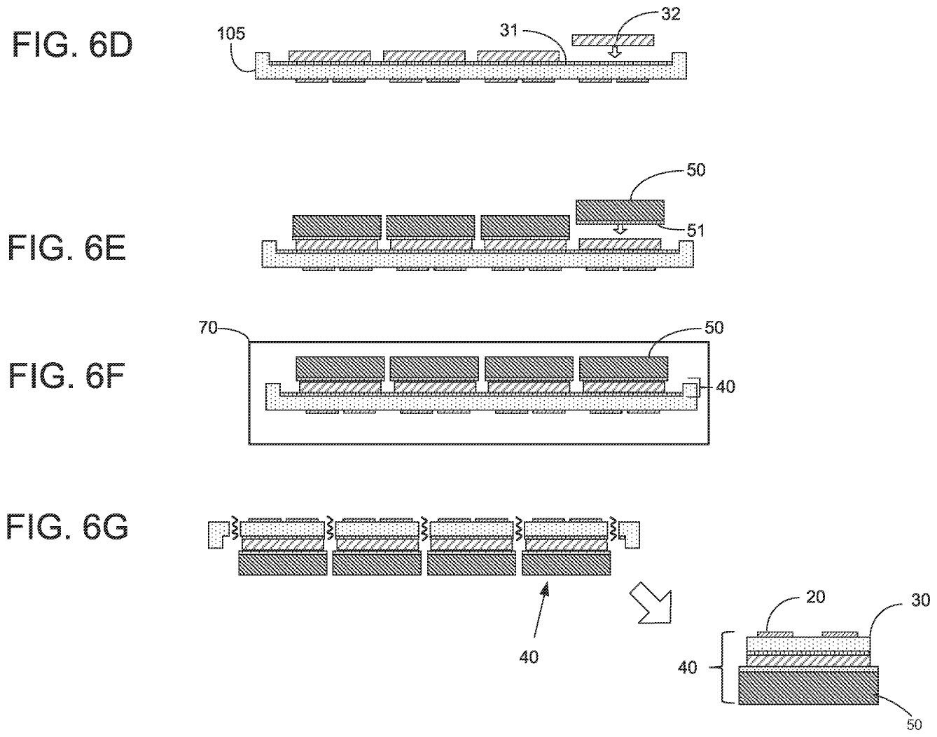

FIGS. 6A-6G schematically illustrate views of a wafer as it is being processed to make the pre-formed vertical device stacks by method 500 shown in FIG. 5.

In method 500 at step 510, selecting a wafer on a frontside (e.g., active side) of which the devices are fabricated may include selecting a silicon wafer (e.g., wafer 100, FIG. 6A) on which devices 20 have been fabricated (e.g., using semiconductor industry device fabrication techniques) as a source of device dies for making the pre-formed device die-block combinations in one or more wafer level steps. FIG. 6A is a plan view of an example silicon wafer 100 having devices 20 formed thereon. Wafer 100 may be used as a source of the device dies (e.g., device die 30).

In example implementations, in method 500 at step 510, selecting a wafer on a frontside of which the devices are fabricated may include selecting a thinned silicon wafer (e.g., a back ground wafer) with a support ring (e.g., a thinned wafer support ring) that is obtained by grinding an inner portion of the silicon wafer (e.g., from a backside) to a desired thinness, while leaving (i.e., not grinding) an outer ring (e.g., thinned wafer support ring) within a defined distance from an edge of the silicon wafer. The support ring may then be used to enable stabilized handling of the thinned wafer, and to provide structural support to thereby prevent warping, chipping, or breaking of the silicon wafer during device fabrication and subsequent processes (e.g., of method 500). The support ring may be removed prior to, or along with, a dicing of the individual devices, circuits or circuit elements fabricated on the wafer. An example of a thinned wafer with a support ring is shown in at least FIG. 6B and FIG. 6C.

FIG. 6B and FIG. 6C show a plan view and a cross-sectional view, respectively, of an example thinned wafer 105 with a support ring 102 (e.g., thinned wafer support ring) obtained after grinding an inner portion of a semiconductor substrate (e.g., a silicon wafer) from a backside of the semiconductor substrate. Thinned wafer 105 may, for example, be only about 25 microns to 150 microns thick (e.g., 80 microns). An example high-power device 20 (e.g., an insulated-gate bipolar transistor (IGBT), a fast recovery diode (FRD), etc.) fabricated on wafer 105 may have a cross sectional area that, for example, exceeds 150 square millimeters. Support ring 102 may provide structural support to thinned wafer 105 as it is being handled and processed through various semiconductor device fabrication tools.

Selection of a wafer (e.g., a thinned wafer 105 with a support ring 102) as a source of devices 20 (as described at step 510 of method 500 (FIG. 5)) may further include preparing the wafer for bonding or fusing to conductive spacer blocks (conductive spacer blocks 50) at a wafer level. Preparing the wafer for bonding or fusing to conductive spacer blocks may, for example, include (e.g., as shown in FIG. 6D) depositing a back metal layer 31 (e.g., a titanium/nickel/silver layer) on the backside (i.e., the side opposite the side on which devices 20 are fabricated) of the wafer.

In method 500 at step 530 (FIG. 5) placing conductive spacer blocks on the coupling mechanism material layer may include (e.g., as shown in FIG. 6E) using a pick-and-place tool to place blocks of coupling mechanism material on the backside of wafer 105 in alignment with devices 20 that are on the frontside of wafer 105. The blocks of coupling mechanism material may include, for example, preform sinter material, solder, or other materials that can promote bonding or fusion with the spacer blocks (e.g., conductive spacer block 50). The blocks of coupling mechanism material (e.g., preform sinter material, solder, etc.) may be about 50 microns to 150 microns thick (e.g., 100 microns thick). FIG. 6D shows, for example, blocks of coupling mechanism material (e.g., blocks 32) being placed on the backside of wafer 105 in alignment with devices 20 that are on the frontside of wafer 105 (as described at step 520 of method 500 (FIG. 5)).

In method 500 at step 530 (FIG. 5), placing conductive spacer blocks on the coupling mechanism material layer may include (e.g., as shown in FIG. 6E) using a pick-and-place tool to align and place individual conductive spacer block on the backside of the wafer. FIG. 6E shows, for example, individual spacer blocks 55 being aligned with, and placed on, blocks 32 on the backside of wafer 105, at step 530 of method 500. In example implementations, in method 500 at step 530 (FIG. 5) placing conductive spacer blocks on the coupling mechanism material layer may also include (e.g., as shown in FIG. 6E) coating a surface of conductive spacer blocks 50 (i.e., the side facing block 32) with a metal layer (e.g., a plated silver layer greater than 2 microns thick) to promote bonding or fusion of conductive spacer blocks 50 with blocks 32.

Each conductive spacer block 50 may have a lateral dimension (e.g., perpendicular to the frontside of wafer 105) that is the same as or bigger than (e.g., slightly bigger than) a lateral dimension of device die 30.

In method 500 at step 540 (FIG. 5), activating the coupling mechanism material layer to bond the conductive spacer blocks to the backside of the selected wafer may, for example, include (e.g., as shown in FIG. 6F) pressure sintering, or solder reflow, or fusion bonding. FIG. 6F shows wafer 105 (with conductive spacer blocks 50 placed on the backside of the wafer) being subject to, for example, pressure sintering (e.g., in a pressure chamber 70) to bond are fuse conductive spacer blocks 50 and the backside of wafer 105 (as described at step 540 of method 500 (FIG. 5)). In alternative implementations, a solder reflow process or a fusion process may be used bond of fuse conductive spacer blocks 50 and the backside of wafer 105.

In method 500 at step 550 (FIG. 5), singulating the wafer to separate the pre-formed vertical device stacks (e.g., as shown in FIG. 6G) may include blade sawing, laser sawing, plasma etching, or a combination thereof, to separate the individual pre-formed individual vertical device stacks. FIG. 6G shows wafer 105 being singulated (diced), for example, to separate pre-formed individual vertical device stacks 40 (in which the bonded or fused spacer blocks structurally reinforce individual device die 30) (as described at step 550 of method 500 (FIG. 5)).

The individual preformed vertical device stacks 40 may be used in assembly of circuit packages (e.g., circuit package 200, circuit package 400, etc.). In the circuit packages, individual pre-formed vertical device stacks 40 (in which the bonded or fused spacer blocks structurally reinforce individual device die 30) are placed between, and in thermal contact with, a pair of opposing substrates (e.g., e.g., substrate 140 and substrate 150) (e.g., as shown in FIG. 2).

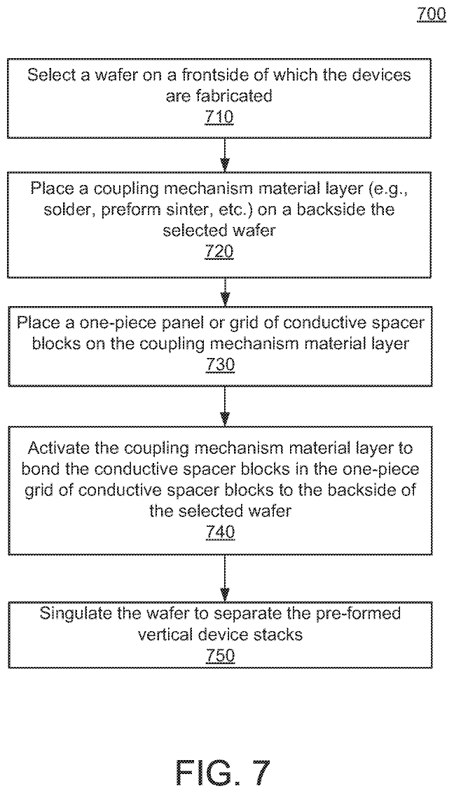

FIG. 7 illustrates an example method 700 that, like method 500 (FIG. 5), avoids handling of individual device die (e.g., device die 30) by using wafer-level processing steps when making vertical device stacks (e.g., vertical device stack 40) for assembly of a circuit package (e.g., circuit package 200, circuit package 400, etc.). Method 700, like method 300 (FIG. 3) and method 500 (FIG. 5), can result in a pre-formed vertical device stack (e.g., pre-formed vertical device stack 40) that is a device die-block combination in which a conductive spacer block structurally reinforces the individual device die (which may be large-sized and thin).

Method 700, like method 500 (FIG. 5), avoids handling individually diced device die 30 by using wafer-level processing steps to make the vertical device stacks (e.g., pre-formed vertical device stack 40). Method 700 includes selection of a wafer on a frontside of which the devices are fabricated (710); placing a coupling mechanism material layer (e.g., a solder, a preform sinter, etc.) on a backside of the selected wafer (720); placing a one-piece panel or grid of conductive spacer blocks on the coupling mechanism material layer (730); activating the coupling mechanism material layer to bond the conductive spacer blocks in the one-piece grid of conductive spacer blocks to the backside of the selected wafer (740); and, singulating the wafer to separate the pre-formed vertical device stacks (750).

Steps 710 and 720 of method 700 (FIG. 7) may be the same as steps 510 and 520 of method 500 (FIG. 5). Views of a wafer being processed at steps 710 and step 720 of method 700 (FIG. 7) may, for example, be the same as the views of wafer 105 shown in FIG. 6B, FIG. 6C and FIG. 6D (which schematically illustrate views of a wafer as it is being processed at steps 510 and step 520 of method 500 (FIG. 5)).

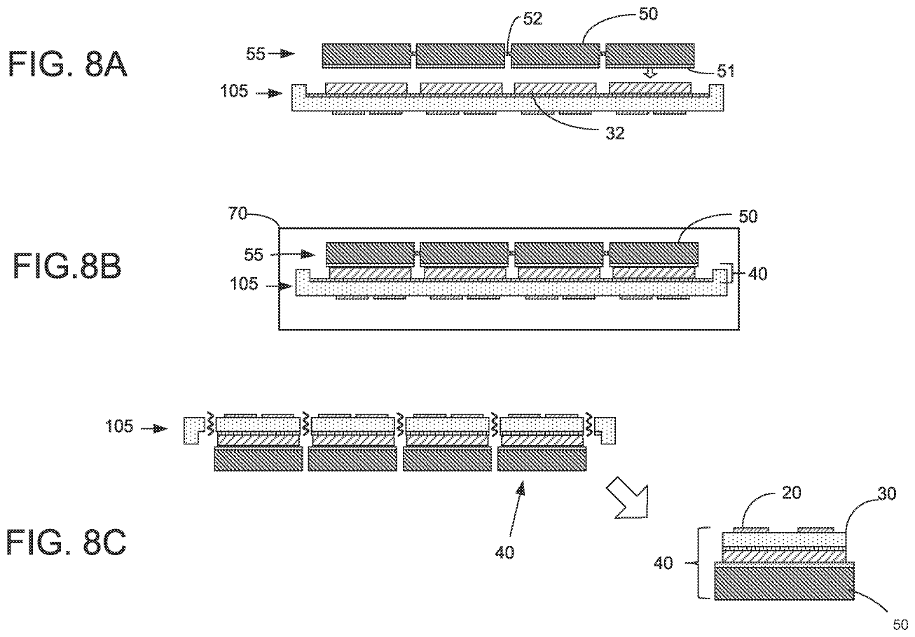

FIGS. 8A-8C illustrate views of the wafer as it is being further processed at subsequent steps 730 through 750 of method 700 (i.e., after blocks of coupling mechanism material (e.g., blocks 32) are placed on the backside of wafer 105 at step 720 of method 700).

In method 700 (FIG. 7), placing a one-piece panel or grid of conductive spacer blocks on the coupling mechanism material layer 730 may include (e.g., as shown in FIG. 8A) aligning the conductive spacer blocks with blocks of the coupling mechanism material layer. FIG. 8A shows a one-piece panel or grid of conductive spacer blocks 55 being aligned and placed on the coupling mechanism material layer (e.g., blocks 32) that are placed on the backside of wafer 105, at step 730 of method 700.

One-piece grid of spacer blocks 55 may have, for example, a planar shape conforming to a shape of wafer 105, and may include a number of rectangular-shaped conductive spacer blocks 50 made of conductive material (e.g., Cu, Al, CuMo, AlSiC, AlSiMg, etc.). In example implementations, in method 700 at step 730 placing a one-piece panel or grid of conductive spacer blocks on the coupling mechanism material layer may also include coating a surface of conductive spacer blocks 50 (i.e., on a side facing block 32) with a metal layer 51 (e.g., a plated silver layer which is greater than 2 microns thick) to promote bonding or fusion of the conductive spacer blocks with blocks 32.

In example implementations, in method 700 at step 730, placing a one-piece panel or grid of conductive spacer blocks on the coupling mechanism material layer may further include (e.g., as shown in FIG. 8A) using a one-piece panel or grid of conductive spacer blocks (e.g., one-piece grid of spacer blocks 55) in which each conductive spacer block 50 is connected to an adjacent spacer block by a connecting strip or neck 52. Connecting strips or necks 52 may be made of the same materials (e.g., Cu, Al, CuMo, AlSiC, AlSiMg, etc.) as conductive spacer blocks 50. Connecting strips or necks 52 may mechanically chain or hold together conductive spacer blocks 50 in grid of spacer blocks 55 as a single piece or unit.

Each conductive spacer block 50 may have a lateral dimension (e.g., perpendicular to the frontside of wafer 105) that is the same as or bigger than (e.g., slightly bigger than) a corresponding lateral dimension of device die 30. A thickness dimension (e.g., a cross-sectional thickness) of the connecting strips or necks may be substantially smaller than a cross-sectional dimension of conductive spacer block 50.

In method 700 at step 730, placing a one-piece panel or grid of conductive spacer blocks on the coupling mechanism material layer 730 may also include (e.g., as shown in FIG. 8A) aligning each conductive spacer block 50 in the one-piece grid of conductive spacer blocks with a respective device die 30 when one-piece grid of spacer blocks 55 is placed as a single unit on blocks 32 on the backside of wafer 105.

Using the one-piece grid of block 55 enables aligning and placing a large number conductive spacer blocks 50 over a correspondingly large number of device dies 30 in a single action. In alternative implementations, as in method 500 (FIG. 5), individual conductive spacer blocks 50 may be placed one-by-one over respective device dies 30 using, for example, a pick and place tool.

In method 700 at step 740, activating the coupling mechanism material layer to bond the conductive spacer blocks to the backside of the selected wafer may, for example, include (e.g., as shown in FIG. 8B) pressure sintering, or solder reflow, or fusion bonding. FIG. 8B shows that wafer 105 (with one-piece grid of spacer blocks 55 aligned and placed on the backside of the wafer) may, for example, be subject to pressure sintering (e.g., in a pressure chamber 70) to bond of fuse conductive spacer blocks 50 and the backside of wafer 105 (at step 740 of method 700 (FIG. 7)). In alternative implementations, a solder reflow process or a fusion process may be used bond of fuse conductive spacer blocks 50 and the backside of wafer 105.

In method 700 at step 750, singulating the wafer to separate the pre-formed vertical device stacks (like step 550 of method 500 (FIG. 5), and as shown for example in FIG. 8C) may include blade sawing, laser sawing, plasma etching, or a combination thereof, to separate the individual pre-formed individual vertical device stacks.

FIG. 8C shows wafer 105 may be singulated (diced) to isolate vertical device stacks 40 (in which the bonded or fused conductive spacer blocks structurally reinforce individual device die 30) (at step 750 of method 700 (FIG. 7)). A singulating process that dices wafer 105, and cuts through or breaks connecting strips or necks 52 that join adjacent conductive spacer blocks 50 (in the one-piece grid of spacer blocks 55 placed on the backside of the wafer) may be used to isolate and separate individual vertical device stacks 40. The singulating process may use a laser beam or a cutting saw to isolate and separate individual vertical device stacks 40.

Further, in method 700 (FIG. 7), as described for method 300 (FIG. 3) and method 500 (FIG. 5), the individual vertical device stacks 40 may be used in assembly of circuit packages (e.g., circuit package 200, circuit package 400, etc.). In the circuit packages, individual vertical device stack 40 (in which the bonded or fused spacer blocks structurally reinforce individual device die 30) are placed between, and in thermal contact with, a pair of opposing substrates (e.g., substrate 140 and substrate 150) (e.g., as shown in FIG. 2).

As noted previously, in example implementations, a circuit package (e.g., a double sided direct cooled power module package) may include more than one semiconductor device die enclosed within a pair of opposing substrates (e.g., substrate 140 and substrate 180, FIG. 2) that are separated by an inter-substrate distance d. In example implementations, in order to maximize performance, different power devices in a circuit package (power module) may have different die thickness.

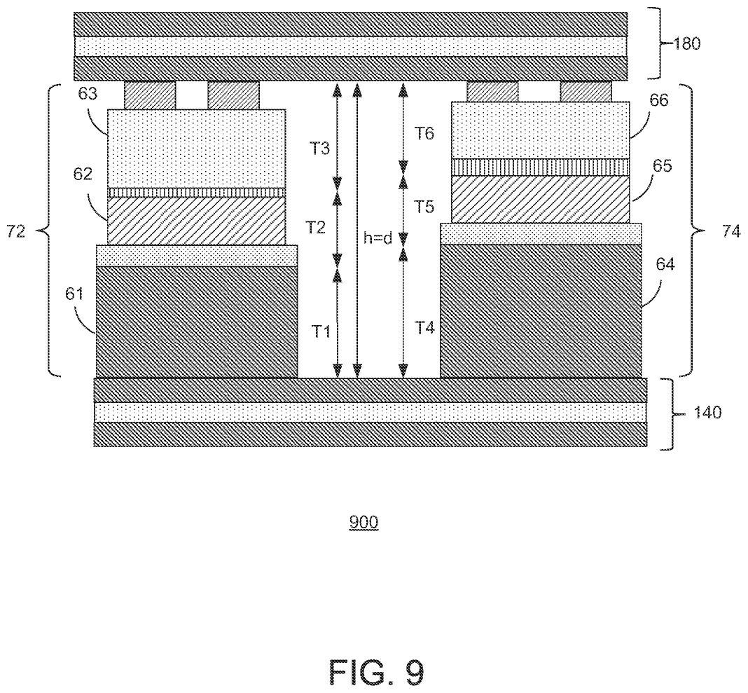

For example, as shown in FIG. 9, different semiconductor device die (e.g., device die 63, device die 66) in a circuit package 900 may have different thicknesses (e.g., T1 and T6, respectively). The different semiconductor device die (e.g., device die 63, device die 66) may be used to assemble different vertical device stacks (e.g., pre-formed vertical device stack 72 and pre-formed vertical device stack 74, respectively) that are enclosed within the pair of opposing substrates (e.g., substrate 140 and substrate 180) (that are separated by an inter-substrate distance d) in the circuit package. For maintaining parallelism of the enclosing pair of opposing substrates (e.g. substrate 140 and substrate 180, FIG. 2), the different vertical device stacks (e.g., pre-formed vertical device stack 72 and pre-formed vertical device stack 74) should have about a same height h as the inter-substrate distance d (i.e., h˜d).

Using any of the methods (e.g., methods 300, 500 or 700 shown in FIG. 3, FIG. 5 and FIG. 7, respectively) for assembling the pre-formed vertical device stacks described herein, the same height h for the different pre-formed vertical stacks can be obtained by using different thicknesses of the conductive material components (e.g., coupling mechanism 32, conductive spacer blocks 50, solders, etc.) to compensate for the different semiconductor device die thicknesses in the vertical device stacks. For example, in the example shown in FIG. 9, pre-formed vertical device stack 72 including device die 63 (having a thickness T3 #thickness T6 of device die 66) may be assembled with coupling mechanism 62 having a thickness T2 and a conductive spacer block 61 having a thickness T1 such that a total thickness T1+T2+T3 is about the same as a target height h for pre-formed vertical device stack 72. Similarly, pre-formed vertical device stack 74 including device die 66 (having a thickness T6+thickness T3 of device die 66) may be assembled with coupling mechanism 65 having a thickness T5 and a conductive spacer block 64 having a thickness T4 such that a total thickness T4+T5+T6 is about the same as a target height h for pre-formed vertical device stack 74. In this example, the difference in semiconductor device die thicknesses (i.e., T3−T6) is compensated by the difference in thickness (i.e., (T1+T2)−(T4+T5)) of the conductive material components (e.g., coupling mechanism 32, conductive spacer blocks 50, solders, etc.) used in the vertical device stacks.

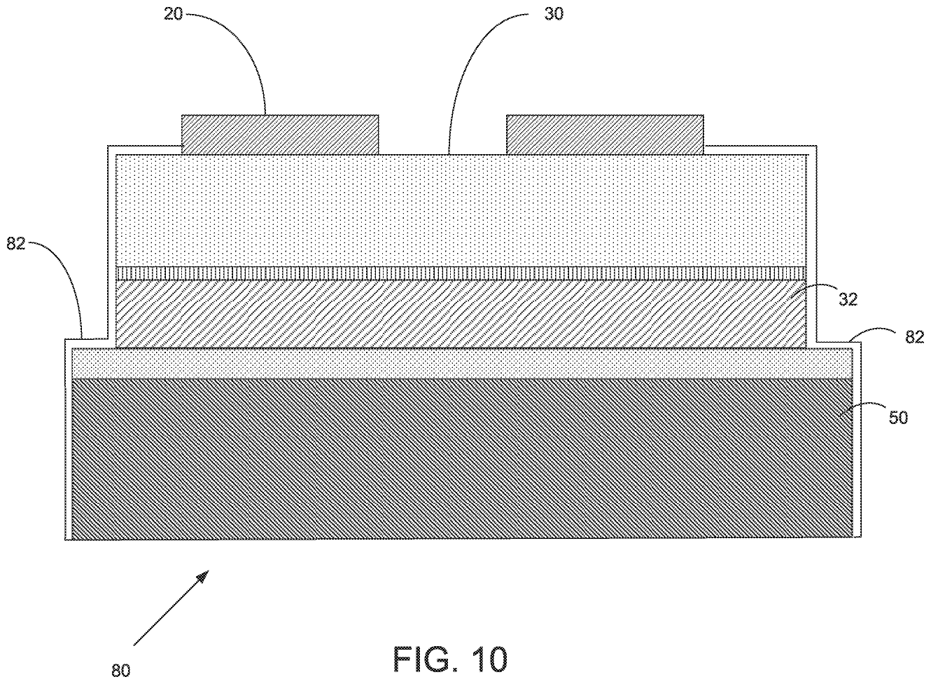

In example implementations, the methods for assembling the vertical device stacks described herein (e.g., method 300 (FIG. 3), method 500 (FIG. 5, and method 700 (FIG. 7)) may further include depositing a passivating layer on the sides of the pre-formed vertical device stacks. FIG. 10 shows, for example, a pre-formed vertical device stack 80 including a device die 30, a solder material layer 32, and a conductive spacer block 50. A passivating layer 82 is deposited on its sides (e.g., vertical sides of vertical device stack 80). Passivating layer 82 may, for example, include passivation material such as high power type shunt resistor (PSR) material, epoxy, oxide, nitride, etc. Passivating layer 82 may protect vertical device stack 80, for example, from solder shorts or other electrical shorts that may occur due to unintended contact or touching of the components in an assembled circuit package (e.g., circuit package 200, FIG. 2). Such unintended contact or touching may occur due to misalignment of the components, or flexure of the circuit package substrates (e.g. substrate 140), for example, during processes for assembling a circuit package (e.g., dual-side-cooled power module) in a flip chip configuration including placement of middle spacers in the circuit package.

In accordance with the principles of the present disclosure, wafer-level processing steps can be used for depositing a passivating layer (e.g., passivating layer 82) on the sides of the pre-formed vertical device stacks (e.g., pre-formed vertical device stack 80). These wafer-level processing steps may, for example, be carried out in conjunction with processes for dicing or separating individual pre-formed vertical device stacks assembled on wafer 105.

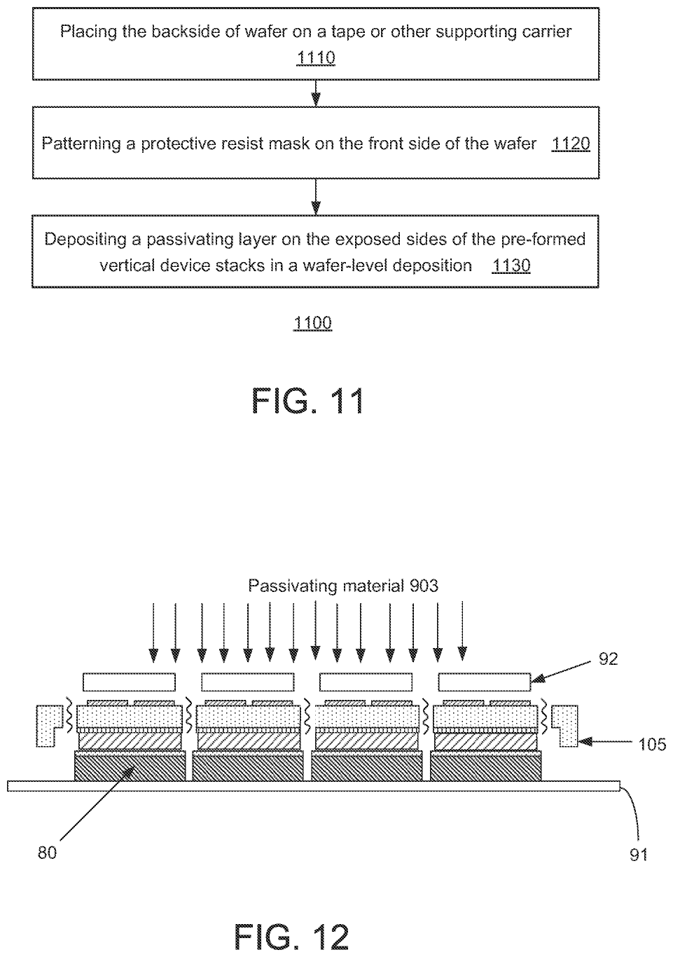

FIG. 11 shows an example method 1100 for depositing a passivating layer (e.g., passivating layer 82) on the sides of the pre-formed vertical device stacks using wafer-level processing steps, in accordance with the principles of the present disclosure. The wafer-level processing steps may, for example, be carried out in conjunction with processes (e.g., at step 350 in method 300 (FIG. 3), at step 550 in method 500 (FIG. 5), at step 750 in method 700 (FIG. 7)) for dicing or separating individual pre-formed vertical device stacks assembled, for example, on wafer 105.

Method 1100 may involve placing the backside of wafer 105 on a tape or other supporting carrier (1110) before or after singulation (e.g., at step 350 in method 300 (FIG. 3), at step 550 in method 500 (FIG. 5), at step 750 in method 700 (FIG. 7))) that separates the individual pre-formed vertical stacks assembled on wafer 105. Method 1100 further includes patterning a protective resist mask on the front side of wafer 105 (1120) to protect the devices (e.g. device 20) fabricated on the frontside of wafer 105.

FIG. 12 schematically illustrates a cross-sectional view of a wafer as it is being processed to deposit a passivating layer deposited on the sides of vertical device stacks (e.g., by method 1100 (FIG. 11)).

FIG. 12 shows, for example, the backside of wafer 105 placed on a tape 91 for support, and a patterned mask 92 placed on the frontside of wafer 105 to protect devices 20 (at step 1120 of method 1100 (FIG. 11)).

After singulation, which separates individual pre-formed vertical stacks 80 and exposes sides of the separated individual vertical stacks, method 1100 (FIG. 11) includes depositing a passivating layer (e.g., passivating layer 82) on the exposed sides of the pre-formed vertical device stacks in a wafer-level deposition (1130). The passivating layer may be deposited through patterned openings in mask 92 using sputtering, evaporation, or other material transfer techniques. In FIG. 12, the deposition of the passivating layer is schematically depicted by downward pointing arrows 93.

In example implementations, a pre-formed vertical device stack (e.g., vertical device stack 40, FIG. 1) is configured to be moved and placed in a circuit package as a single pre-formed unit. The pre-formed vertical device stack includes a vertical arrangement of thin device die, and a conductive spacer block bonded to the thin device die via a coupling mechanism. The thin device die is, for example, about 100 microns thick or less, and includes a power device (e.g., IGBT, FRD) having an areal size that is, for example, greater than 25 square millimeters. The conductive spacer block has a thickness that is, for example, greater than about 200 microns. The conductive spacer block bonded to the thin device die reinforces the mechanical strength of the thin device die. In one or more example implementations, exposed sides of the pre-formed vertical device stack may be covered by a passivating material layer, for example, to avoid solder shorts.

It will be understood that, in the foregoing description, when an element, such as a layer, a region, a substrate, or component is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in the specification and claims, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

1. (canceled)

2. A method, comprising:
placing a coupling mechanism material layer on a backside of a wafer that has devices fabricated on a frontside thereof;
placing a one-piece panel of spacer blocks on the coupling mechanism material layer on the backside of the wafer;
activating the coupling mechanism material layer to bond the spacer blocks in the one-piece panel of spacer blocks to the backside of the wafer; and
singulating the wafer to separate individual vertical device stacks, each of the individual vertical device stacks including a device die bonded to a spacer block.

3. The method of claim 2, wherein each spacer block in the one-piece panel of spacer blocks is connected to adjacent spacer blocks by connecting strips, and wherein the connecting strips mechanically hold together the spacer blocks in the one-piece panel of spacer blocks as a single piece or unit.

4. The method of claim 2, each spacer block is made of a metal or a metal alloy.

5. The method of claim 4, wherein the metal or the metal alloy includes at least one of copper (Cu), aluminum (Al), copper-molybdenum (CuMo), aluminum silicon carbide composite (AlSiC), or aluminum silicon magnesium alloy (AlSiMg).

6. The method of claim 4, wherein a side of each spacer block facing the coupling mechanism material layer is coated with a plated silver layer.

7. The method of claim 3, wherein singulating the wafer to separate the individual vertical device stacks includes cutting the connecting strips that mechanically hold together the spacer blocks in the one-piece panel of spacer blocks.

8. The method of claim 2 further comprising depositing a passivation layer on exposed sides of the individual vertical device stacks in a wafer-level deposition process.

9. The method of claim 2, wherein activating the coupling mechanism material layer to bond the spacer blocks to the backside of the wafer includes at least one of pressure sintering, solder reflow and fusion bonding.

10. The method of claim 2, wherein the device die includes at least one of a fast recovery diode (FRD) or an insulated gate bipolar transistor (IGBT).

11. The method of claim 2, further comprising thinning the wafer prior to placing the coupling mechanism material layer and placing the one-piece panel of spacer blocks on the coupling mechanism material layer on the backside of the wafer.

12. The method of claim 11, wherein thinning the wafer includes back grinding an inner portion of the wafer while leaving a wafer support ring at an edge of the wafer.

13. The method of claim 2, wherein the device die is about 100 microns thick or less.

14. The method of claim 2, wherein the device die includes a power device having a size that is greater than 25 square millimeters.

15. The method of claim 2, wherein the spacer block has thickness in a range of about 100 microns to 2500 microns, and wherein the coupling mechanism material layer has thickness in a range of about 50 microns to 300 microns.

16. An assembly, comprising:
a semiconductor wafer with an array of devices fabricated on a frontside thereof;
a coupling mechanism material layer disposed on a backside of the semiconductor wafer; and
a one-piece panel of spacer blocks disposed on the coupling mechanism material layer, the one-piece panel of spacer blocks including an array of spacer blocks with connecting strips of metal joining adjacent spacer blocks, the spacer blocks in the one-piece panel of spacer blocks being bonded to the backside of the semiconductor wafer,
the connecting strips joining adjacent spacer blocks in the one-piece panel of spacer blocks being severable in a wafer singulation action to separate individual vertical device stacks, each of the individual vertical device stacks including a device die bonded to a spacer block.

17. The assembly of claim 16, wherein the spacer blocks are made of a metal or a conductive metal alloy including at least one of copper (Cu), aluminum (Al), copper-molybdenum (CuMo), aluminum silicon carbide composite (AlSiC), or aluminum silicon magnesium alloy (AlSiMg).

18. The assembly of claim 16, wherein the device die is about 100 microns thick or less.

19. The assembly of claim 16, wherein the coupling mechanism material layer disposed on the backside of the semiconductor wafer has a thickness greater than about 200 microns.

20. The assembly of claim 16, wherein the one-piece panel of spacer blocks has a planar shape conforming to a shape of the semiconductor wafer.

21. The assembly of claim 16, wherein each of the individual vertical device stacks is configured to be moved and placed in a circuit package as a single pre-formed unit.
